(19) United States
(12) Patent Application Publication
(10) Pub. No.: US 2015/0332911 A1
(43) Pub. Date: Nov. 19, 2015

(54) METHOD OF PROCESSING WAFER

(71) Applicant: DISCO CORPORATION, Tokyo (JP)

(72) Inventor: Karl Heinz Priewasser, Muenchen (DE)

(21) Appl. No.: 14/713,690

(22) Filed: May 15, 2015

(30) Foreign Application Priority Data
May 16, 2014 (JP) 2014-101993

(51) Int. Cl. H01L 21/02; B32B 38/10; B32B 37/12; B32B 38/00; H01L 21/683; B32B 37/18

(52) U.S. Cl. CPC H01L 21/02021; H01L 21/02013; H01L 21/6835; B32B 37/18; B32B 37/12; B32B 38/0004; B32B 38/10; H01L 2221/68327; B32B 2457/14

(57) ABSTRACT

A wafer has a device region on a front surface where a plurality of devices are disposed and an outer circumferential excess region surrounding the device region. The wafer has a chamfered portion of arcuate cross section on an outer circumferential edge thereof, the chamfered portion extending from the front surface to a reverse side of the wafer. A sheet having an adhering capability and tack strength with respect to the wafer is applied to the front surface of the wafer with an adhesive placed on the outer circumferential excess region. Then a cutting blade cuts into the chamfered portion by a predetermined depth from the front surface of the wafer, and the wafer is cut along the outer circumferential edge thereof to remove part of the chamfered portion and keep part of the adhesive adjacent to at least the device region unremoved.

### BACKGROUND OF THE INVENTION

1. Field of the Invention

The present invention relates to a method of processing a wafer, and more particularly to an edge trimming method of partially removing a chamfered portion on the outer circumferential edge of a wafer.

2. Description of the Related Art

Semiconductor wafers have many devices such as ICs, LSI circuits, etc. formed on their front surfaces and divided by a grid-like pattern of division lines (streets). Such a semiconductor wafer is machined to a predetermined thickness by having its reverse side ground by a grinding device, and then cut into individual devices along the division lines by a cutting apparatus (dicing saw). The divided devices are widely used in various electronic devices such as mobile phones, personal computers, etc. To meet demands in recent years for smaller electronic devices, semiconductor wafers, which may hereinafter be referred to simply as “wafers,” with a plurality of devices formed thereon are required to be ground to a smaller thickness, e.g., a thickness of 100 μm or less, or a thickness of 50 μm or less. Depending on devices to be fabricated, the step of grinding the reverse side of a wafer may be followed by other steps, such as the step of covering the reverse side with a metal film and the step of cleaning the reverse side.

In order to prevent a wafer from being cracked or from producing dust during the fabrication process, the outer circumferential edge of the wafer is chamfered to an arcuate cross-sectional shape extending from the front surface to reverse side thereof. Therefore, when the wafer is ground to a smaller thickness, the chamfered outer circumferential edge of the wafer is shaped like a knife edge. However, the chamfered outer circumferential edge of the wafer that has been shaped like a knife edge tends to chip off, breaking the wafer. Japanese Patent Laid-open No. 2007-152906 discloses a wafer processing method in which the chamfered outer circumferential edge of a wafer is partly removed with a cutting blade, i.e., an edge trimming step is carried out, followed by grinding the reverse side of the wafer until the thickness of the wafer becomes a finished thickness for devices to be fabricated from the wafer.

### SUMMARY OF THE INVENTION

However, when the edge trimming step is carried out by cutting into the chamfered outer circumferential edge of the wafer with a cutting blade from the front surface of the wafer, contaminants produced in the edge trimming step are attached to the devices on the front surface of the wafer. The contaminants that are attached to the front surfaces of the devices are problematic because they tend to cause a device failure.

It is therefore an object of the present invention to provide a method of processing a wafer while reducing the risk of causing a device failure even when an edge trimming step is carried out on the wafer.

In accordance with an aspect of the present invention, there is provided a method of processing a wafer having on a front surface thereof a device region where a plurality of devices are formed and an outer circumferential excess region surrounding the device region, the wafer having a chamfered portion of arcuate cross section on an outer circumferential edge thereof, the chamfered portion extending from the front surface to a reverse side of the wafer, the method comprising: a sheet applying step of applying a sheet having an adhering capability and tack strength with respect to the wafer to the front surface of the wafer with an adhesive placed on the outer circumferential excess region; and a removing step of, after the sheet applying step is carried out, cutting into the chamfered portion by a predetermined depth with a cutting blade from the surface of the wafer, and cutting the wafer along the outer circumferential edge thereof to remove part of the chamfered portion and keep part of the adhesive adjacent to at least the device region unremoved.

Preferably, the wafer processing method further includes a grinding step of, after the removing step is carried out, grinding the reverse side of the wafer to a finished thickness of the devices. In the removing step, the cutting blade is pushed into the chamfered portion by a depth corresponding to the finished thickness from the front surface of the wafer.

According to the present invention, before the removing step (edge trimming step), the sheet having the adhering capability and tack strength with respect to the wafer is applied to the front surface of the wafer. Contaminants produced when the part of the chamfered portion is removed are attached to the sheet, but not to the front surfaces of the devices. The sheet is applied to the front surface of the wafer by the adhesive placed on the outer circumferential excess region of the wafer. Therefore, any glue and adhesive are prevented from remaining on the devices when the sheet is subsequently peeled off the wafer. Consequently, the devices are protected against a device failure due to the deposition of foreign matter on the devices.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view showing the surface of a semiconductor wafer;

FIG. 2 is a cross-sectional view illustrating a sheet applying step;

FIG. 3 is a side elevational view, partly in cross section, illustrating a removing step;

FIG. 4 is a cross-sectional view of the wafer after the removing step has been carried out; and

FIG. 5 is a side elevational view, partly in cross section, illustrating a grinding step.

### DETAILED DESCRIPTION OF THE PREFERRED EMBODIMENT

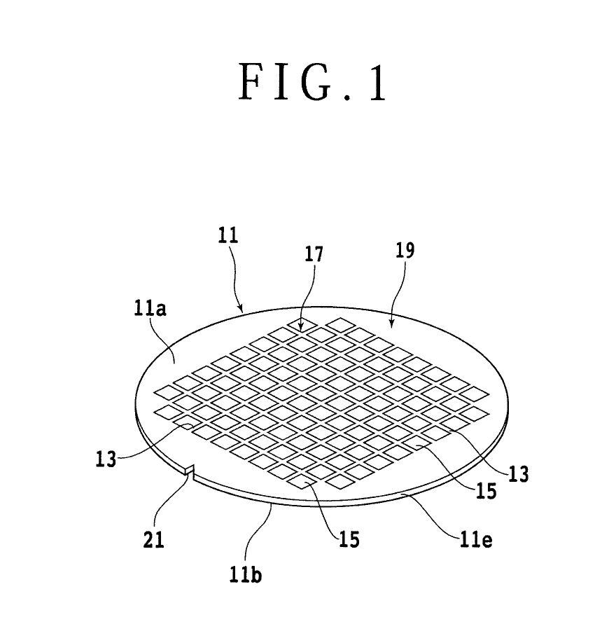

A method of processing a wafer according to an embodiment of the present invention will be described in detail below with reference to the drawings. FIG. 1 shows a front surface of a semiconductor wafer 11 in perspective. The semiconductor wafer 11, which may hereinafter be referred to simply as “wafer 11,” is a silicon wafer having a thickness of 700 μm, for example. The wafer 11 has a grid-like pattern of division lines (streets) 13 on a front surface 11a thereof, and a plurality of devices 15 such as ICs, LSI circuits, etc. formed in areas defined by the streets 13. The wafer 11 thus arranged includes, on a flat portion of the front surface 11a, a device region 17 where the devices 15 are formed and an outer circumferential excess region 19 surrounding the device region 17. The wafer 11 also has a chamfered portion 11e of arcuate cross section on an outer circumferential edge thereof, and a notch 21 defined in the outer circumferential edge as a mark indicating the crystal orientation of the silicon wafer.

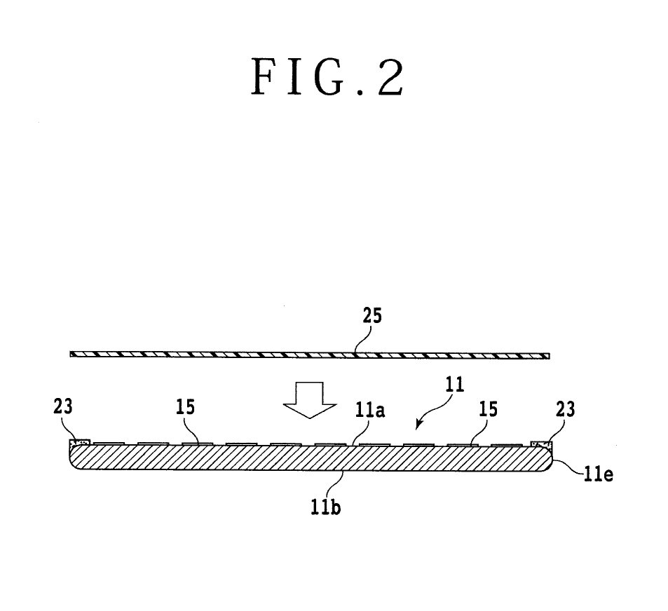

In the method of processing a wafer according to the present invention, as shown in FIG. 2, a sheet applying step is first carried out by placing an adhesive 23 on the outer circumferential excess region 19 of the wafer 11, and applying a sheet 25, which has an adhering capability and tack strength with respect to the wafer 11, to the front surface 11a of the wafer 11 with the adhesive 23 interposed therebetween. The adhesive 23 may be in the shape of a continuous ring which extends fully circumferentially on the outer circumferential excess region 19 of the wafer 11 or may be in the shape of discrete dots disposed at spaced intervals on the outer circumferential excess region 19 of the wafer 11. If the front surface of the wafer 11 is attracted and held by only the sheet 25 when a reverse side 11b of the wafer 11 is ground, then the adhesive 23 should preferably be in the shape of a continuous ring extending fully circumferentially on the outer circumferential excess region 19 so that no grinding water will find its way into the device region 17 of the wafer 11. If a protective tape is applied to the front surface 11a of the wafer 11 after the sheet 25 is peeled off, then the adhesive 23 may be in the shape of discrete dots disposed at spaced intervals on the outer circumferential excess region 19.

The sheet 25 should preferably be a sheet having an ability to adhere to the wafer and tack strength making itself capable of conforming with surface irregularities provided by the devices on the wafer 11, and also having a suitable thickness and firmness making itself easy to handle, though the sheet 25 lacks a sticking layer on its surface for abutting against the devices on the wafer. The sheet 25 may appropriately be made of resin, rubber, or ceramics, and should preferably include a food wrapping film formed of polyvinylidene chloride film known as Saran Wrap (registered trademark), for example. The food wrapping film has an adhering capability and tack strength (attracting capability) with respect to the wafer 11. However, instead of the food wrapping film, any of other resin sheets may be applied as the sheet 25.

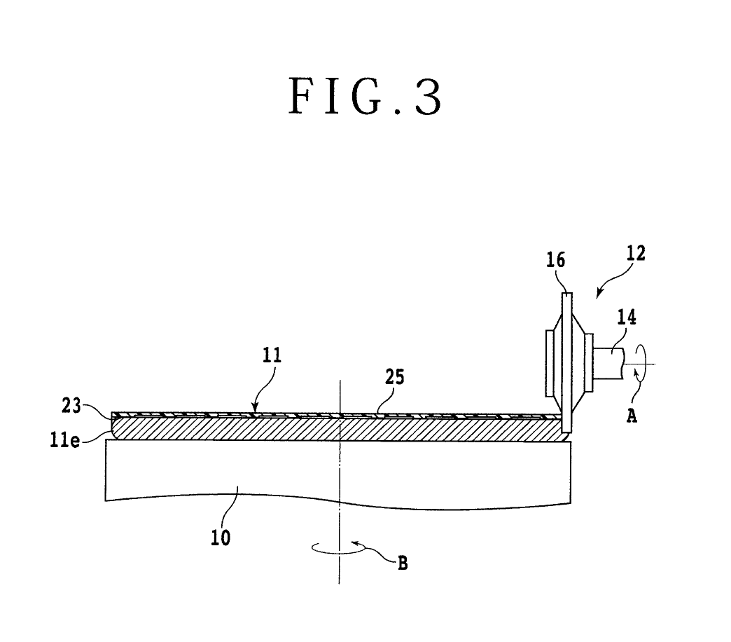

After the sheet applying step is carried out, as shown in FIG. 3, the reverse side 11b of the wafer 11 is attracted and held by a chuck table 10 of a cutting apparatus, exposing the sheet 25. In FIG. 3, the cutting apparatus has a cutting unit 12 including a spindle 14 that is actuated to rotate about its own axis and a cutting blade 16 mounted on the distal end of the spindle 14. The cutting blade 16 should preferably be a so-called washer blade which is thick that has a cutting edge on its entire circumference.

Then, a removing step (edge trimming step) is carried out by pushing the cutting blade 16 which is being rotated at a high speed along the direction indicated by an arrow A from the front surface 11a of the wafer 11 into the chamfered portion 11e thereof by a predetermined depth, i.e., a depth corresponding to a finished thickness from the front surface 11a of the wafer 11, and rotating the chuck table 10 at a low speed along the direction indicated by an arrow B, thereby cutting the wafer 11 along the outer circumferential edge thereof to remove part of the chamfered portion 11e and keep part of the adhesive 23 adjacent to at least the device region 17 unremoved.

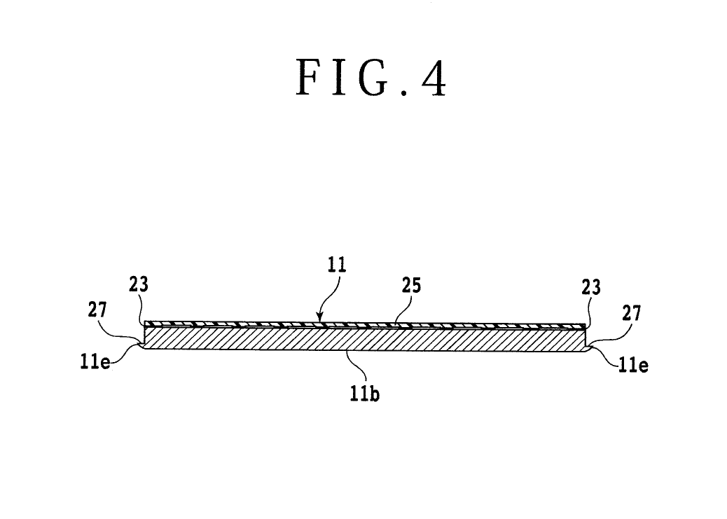

FIG. 4 shows in cross section the wafer 11 after the removing step has been carried out. When the removing step is carried out, part of the chamfered portion 11e of the wafer 11 is removed, leaving an annular recess (annular groove) 27 in the outer circumference of the wafer 11. In the removing step (edge trimming step) according to the present embodiment, since the sheet 25 is applied to the front surface 11a of the wafer 11, contaminants produced in the removing step are attached to the sheet 25, but not to the front surfaces of the devices 15.

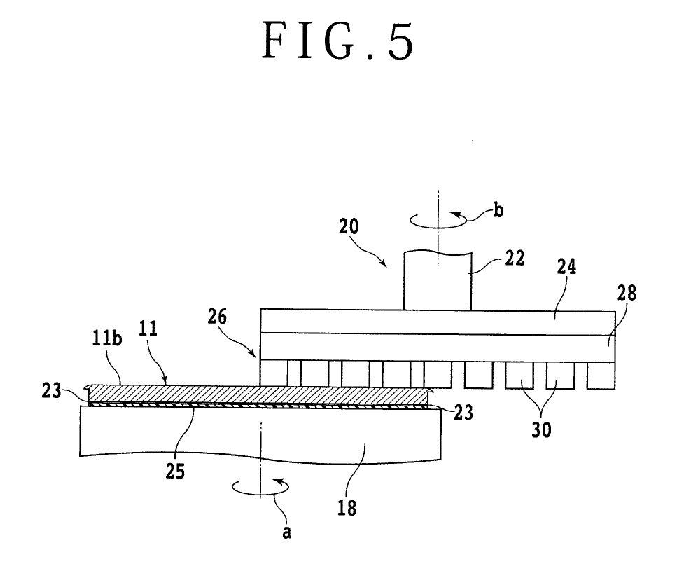

After the removing step, a grinding step is carried out to grind the reverse side 11b of the wafer 11 to a finished thickness of the devices 15. In the grinding step, as shown in FIG. 5, the sheet 25 applied to the front surface 11a of the wafer 11 is attracted and held by a chuck table 18 of a grinding apparatus, exposing the reverse side 11b of the wafer 11. As shown in FIG. 5, the grinding apparatus has a grinding unit 20 including a spindle 22 that is actuated to rotate about its own axis, a wheel mount 24 fixed to the distal end of the spindle 22, and a grinding wheel 26 detachably mounted on the wheel mount 24. The grinding wheel 26 includes an annular wheel base 28 and a plurality of grinding stones 30 attached in an annular array to the outer circumferential area of the lower surface of the wheel base 28.

In the grinding step, while the chuck table 18 is being rotated about its own axis at a rotational speed of about 300 rpm along the direction indicated by an arrow “a,” and the grinding wheel 26 is being rotated about its own axis at a rotational speed of about 6000 rpm along the direction indicated by an arrow “b,” the grinding stones 30 are brought into contact with the reverse side 11b of the wafer 11 by operating a grinding unit feeding mechanism not shown. The grinding unit 20 is fed downwardly at a predetermined feed speed by a predetermined distance thereby to grind the reverse side 11b of the wafer 11 to a finished thickness of the wafer (finished thickness of the devices 15). When the reverse side 11b of the wafer 11 is thus ground, the chamfered portion 11e of the wafer 11 is removed in its entirety.

For grinding the reverse side 11b of the wafer 11, the sheet 25 is peeled off the front surface 11a of the wafer 11. Then, a surface protective tape is applied to the front surface 11a of the wafer 11, after which the grinding step is carried out. Alternatively, the sheet 25 may not be peeled off the front surface 11a of the wafer 11, and a surface protective tape may be applied to the sheet 25.

In the sheet applying step according to the present invention, the sheet 25 is applied to the front surface 11a of the wafer 11 by the adhesive 23 placed on the outer circumferential excess region 19 of the wafer 11. Therefore, after the grinding step, any glue and adhesive is prevented from remaining on the devices 15 when the sheet 25 is peeled off the wafer 11. Consequently, the devices 15 are protected against a device failure due to the deposition of foreign matter on the devices 15.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a wafer having on a front surface thereof a device region where a plurality of devices are formed and an outer circumferential excess region surrounding the device region, the wafer having a chamfered portion of arcuate cross section on an outer circumferential edge thereof, the chamfered portion extending from the front surface to a reverse side of the wafer, the method comprising:
a sheet applying step of applying a sheet having an adhering capability and tack strength with respect to the wafer to the front surface of the wafer with an adhesive placed on the outer circumferential excess region; and
a removing step of, after the sheet applying step is carried out, cutting into the chamfered portion by a predetermined depth with a cutting blade from the front surface of the wafer, and cutting the wafer along the outer circumferential edge thereof to remove part of the chamfered portion and keep part of the adhesive adjacent to at least the device region unremoved.

2. The method of processing a wafer according to claim 1, further comprising:
a grinding step of, after the removing step is carried out, grinding the reverse side of the wafer to a finished thickness of the devices,
wherein, in the removing step, the cutting blade is pushed into the chamfered portion by a depth corresponding to the finished thickness from the front surface of the wafer.
